(19) United States
(12) Patent Application Publication
(10) Pub. No.: US 2014/0145331 A1
(43) Pub. Date: May 29, 2014

(54) MULTI-CHIP PACKAGE AND MANUFACTURING METHOD THEREOF

(71) Applicant: Samsung Electronics Co., Ltd., Gyeonggi-do (KR)

(72) Inventors: DOO-HEE HWANG, Yongin-si (KR); SANG-KIL LEE, Seongnam-si (KR)

(73) Assignee: Samsung Electronics Co., Ltd., Gyeonggi-do (KR)

(21) Appl. No.: 14/056,839

(22) Filed: Oct. 17, 2013

(30) Foreign Application Priority Data
Nov. 27, 2012 (KR) 10-2012-0135352

(51) Int. Cl. H01L 23/498

(52) U.S. Cl. CPC H01L 23/49816
USPC 257/738

(57) ABSTRACT

A multi-chip package may include a system on a chip (SOC) and a plurality of memory devices arranged in the same layer on the SOC. Accordingly, as the multi-chip package may not need to use a TSV, so that manufacturing cost of the multi-chip package is reduced. Moreover, a memory bandwidth between the SOC and the first and second memory devices may increase.

### CROSS-REFERENCE TO RELATED APPLICATION

This application claims priority under 35 U.S.C. §119 to Korean Patent Application No. 10-2012-0135352 filed on Nov. 27, 2012, the disclosure of which is hereby incorporated by reference in its entirety.

### BACKGROUND

Generally, a TSV is used for each of a plurality of memory devices that provide a wide input/output (WIO or WideIO) so that the plurality of memory devices are stacked in a single vertical stack in one package chip. Each of the plurality of memory devices uses the TSV to be electrically connected to a substrate. However, in case of applying the TSV to each of the plurality of memory devices, the TSV portion is added to the memory devices and the cost of fabrication processes for providing the TSV increases.

### SUMMARY

Embodiments disclosed herein provide a multi-chip package that can reduce the manufacturing cost by removing the need for TSVs.

Other embodiments provide a manufacturing method of the multi-chip package.

In one embodiment, a multi-chip package includes: a system on chip (SOC) including a central processing unit (CPU) and a memory controller; a first memory device stacked on the SOC and electrically connected to the memory controller; and a second memory device stacked on the SOC and electrically connected to the memory controller. The first memory device and second memory device are disposed in the same plane.

In one embodiment, the first memory device comprises a first die; and the second memory device comprises a second die separate from the first die.

The first separated portion and second separated portion may be from the same wafer or from different wafers.

In one embodiment, the first memory device and second memory device comprise a single die that forms a chip.

In one embodiment, the multi-chip package includes a first set of micro-bumps physically and electrically connecting the first memory device to the SOC; and a second set of micro-bumps physically and electrically connecting the second memory device to the SOC.

The first set of micro-bumps may form a first WideIO interface; and the second set of micro-bumps may form a second WideIO interface. Each of the first WideIO interface and second WideIO interface may include at least 512 WideIO terminals.

In one embodiment, the multi-chip package further includes a substrate on which the SOC is mounted; and a set of balls electrically and physically connecting the SOC to the substrate. The substrate may be a printed circuit board (PCB).

In one embodiment, a multi-chip package includes: a system on a chip (SOC); a plurality of memory chips arranged in the same layer on the SOC; a first set of terminals physically and electrically connecting a first memory chip of the plurality of memory chips to the SOC; and a second set of terminals physically and electrically connecting a second memory chip of the plurality of memory chips to the SOC. The first set of terminals is horizontally adjacent to the second set of terminals.

The first set of terminals comprise may include a first set of micro-bumps; and the second set of terminals comprise may include a second set of micro-bumps.

In one embodiment, the first set of terminals forms a first wide input/output (WideIO) interface between the SOC and the first memory chip; and the second set of terminals forms a second wide input/output (WideIO) interface between the SOC and the second memory chip. Each of the first WideIO interface and second WideIO interface may include at least 512 WideIO terminals.

In one embodiment, the first memory chip and the second memory chip comprise an unseparated portion of a single wafer.

In one embodiment, the SOC includes a first memory controller for controlling the first memory chip; a second memory controller for controlling the second memory chip; and a central processing unit (CPU). The SOC may further include at least one intellectual property (IP) core for accessing the first memory chip through the first memory controller or for accessing the second memory chip through the second memory controller.

In one embodiment, the first memory chip is physically and electrically connected to the first memory controller through the first set of terminals, and the second memory chip is physically and electrically connected to the second memory controller through the second set of terminals.

The multi-chip package may include a substrate electrically connected to the SOC; and a plurality of solder balls connected to the substrate and for communicating with an external host.

Each of the plurality of memory chips may include a DRAM.

### BRIEF DESCRIPTION OF THE DRAWINGS

FIG. 1 is a block view of a multi-chip package 100 in accordance with one exemplary embodiment.

FIG. 2A shows the front and the side of the multi-chip package 100 shown in FIG. 1, according to one exemplary embodiment.

FIG. 2B is a perspective view of the multi-chip package 100 shown in FIG. 1, according to one exemplary embodiment.

FIG. 2C is a rear view of the multi-chip package 100 shown in FIG. 1, according to one exemplary embodiment.

FIG. 3 is a system view inside the multi-chip package 100 shown in FIG. 1, according to one exemplary embodiment.

FIG. 4 is a front view of a first memory device 110 shown in FIG. 1, according to one exemplary embodiment.

FIG. 5 shows a memory device using a WideIO.

FIG. 6 is a flow chart illustrating a manufacturing method of the multi-chip package 100 shown in FIG. 1, according to one exemplary embodiment.

FIG. 7 is a block view of a multi-chip package 200 in accordance with another exemplary embodiment.

FIG. 8 is an embodiment of a wafer including the chip shown in FIG. 7, according to one exemplary embodiment.

FIG. 9 is a flow chart illustrating a manufacturing method of the multi-chip package 200 shown in FIG. 7, according to one exemplary embodiment.

FIG. 10 is another exemplary embodiment of a wafer including the chip shown in FIG. 7.

FIG. 11 shows a main board 3100 including the multi-chip package 100 shown in FIG. 1, according to one exemplary embodiment.

FIG. 12 shows a graphic card 3200 including the multi-chip package 100 shown in FIG. 1, according to one exemplary embodiment.

FIG. 13 shows a solid state drive (SSD) 3300 including the multi-chip package 100 shown in FIG. 1, according to one exemplary embodiment.

FIG. 14 shows one exemplary embodiment of a computer system 4100 including the multi-chip package 100 shown in FIG. 1.

FIG. 15 shows another exemplary embodiment of a computer system 4200 including the multi-chip package 100 shown in FIG. 1.

FIG. 16 shows another exemplary embodiment of a computer system 4300 including the multi-chip package 100 shown in FIG. 1.

### DETAILED DESCRIPTION OF THE EMBODIMENTS

Various embodiments will now be described more fully with reference to the accompanying drawings in which some embodiments are shown. These inventive concepts may, however, be embodied in different forms and should not be construed as limited to the embodiments set forth herein. In the drawings, the sizes and relative sizes of layers and regions may be exaggerated for clarity.

It will be understood that, although the terms first, second, third, etc. may be used herein to describe various elements, components, regions, layers and/or sections, these elements, components, regions, layers and/or sections should not be limited by these terms. Unless indicated otherwise, these terms are only used to distinguish one element, component, region, layer or section from another region, layer or section. Thus, a first element, component, region, layer or section discussed below could be termed a second element, component, region, layer or section without departing from the teachings of the present inventive concept.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

The terminology used herein is for the purpose of describing particular embodiments only and is not intended to be limiting of the present inventive concept. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments are described herein with reference to cross-sectional, plan view, and perspective illustrations that are schematic illustrations of idealized embodiments (and intermediate structures). As such, variations from the shapes of the illustrations as a result, for example, of manufacturing techniques and/or tolerances, are to be expected. Thus, embodiments should not be construed as limited to the particular shapes of regions illustrated herein but are to include deviations in shapes that result, for example, from manufacturing. For example, ball or bump illustrated with a round, circular shape, may have angular sides, or an oval shape, or other variations. Similarly, an edge illustrated as having a sharp 90 degree angle may have a slightly different angle, or may be slightly curved. Thus, the regions illustrated in the figures are schematic in nature and their shapes are not intended to limit the scope of the present inventive concept.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, desirable embodiments of the inventive concept will be explained referring to the attached drawings.

Embodiments disclosed herein relate to a multi-chip package, and more particularly, to a multi-chip package in which a plurality of memory devices are arranged in the same layer on a system on a chip (SOC). The plurality of memory devices may connect to the SOC without through silicon vias (TSVs).

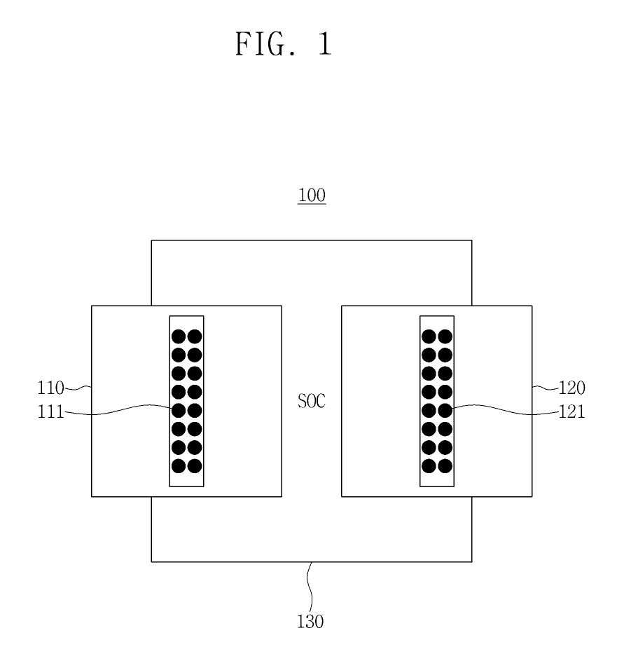

FIG. 1 is a block view of a multi-chip package 100 in accordance with one exemplary embodiment.

Referring to FIG. 1, the multi-chip package 100 according to one embodiment includes first and second memory devices 110 and 120 arranged on the same plane (for example, the same layer), and a system on a chip (SOC) 130 controlling the first and second memory devices.

The first and second memory devices 110 and 120 are arranged on a top of the SOC 130 in a non-overlapping state. For example, each of the first and second memory devices 110 and 120 are stacked on the SOC 130 on a same surface of the SOC 130, so that first memory device 110 and second memory device 120 are coplanar. In one embodiment, the first memory device 110 includes a first set of terminals, such a first set of micro bumps 111 that are physically and electrically connected to the SOC 130, and the second memory device 120 includes a second set of terminals, such as a second set of micro bumps 121 that are physically and electrically connected to the SOC 130. As shown in FIG. 1, the first set of terminals may be horizontally adjacent the second set of terminals. Each of the first and second sets of micro bumps 111 and 121 may include a plurality of micro bumps. Each micro bump of the first and second sets of micro bumps 111 and 121 may be formed, for example, in a hemispherical or convex shape, and may contain Ni, Au, Cu or a solder alloy.

Each of the first and second memory devices 110 and 120 may be a die manufactured from the same wafer or from different wafers. For example, each of the first and second memory devices 110 and 120 may be a die sawn from the same wafer. Also, each of the first and second memory devices 110 and 120 may be a die respectively sawn from different wafers. As described further below, the first and second memory devices 110 and 120 can be formed as separate individual chips (e.g., dies separated from each other) or as a single chip (e.g., dies connected to each other).

In certain embodiments, each of the first and second memory devices 110 and 120 may include a dynamic random access memory (DRAM) or non volatile memories such as a ferroelectric random access memory (FeRAM), a phase-change random access memory (PRAM), a magnetic random access memory (MRAM), or a flash memory.

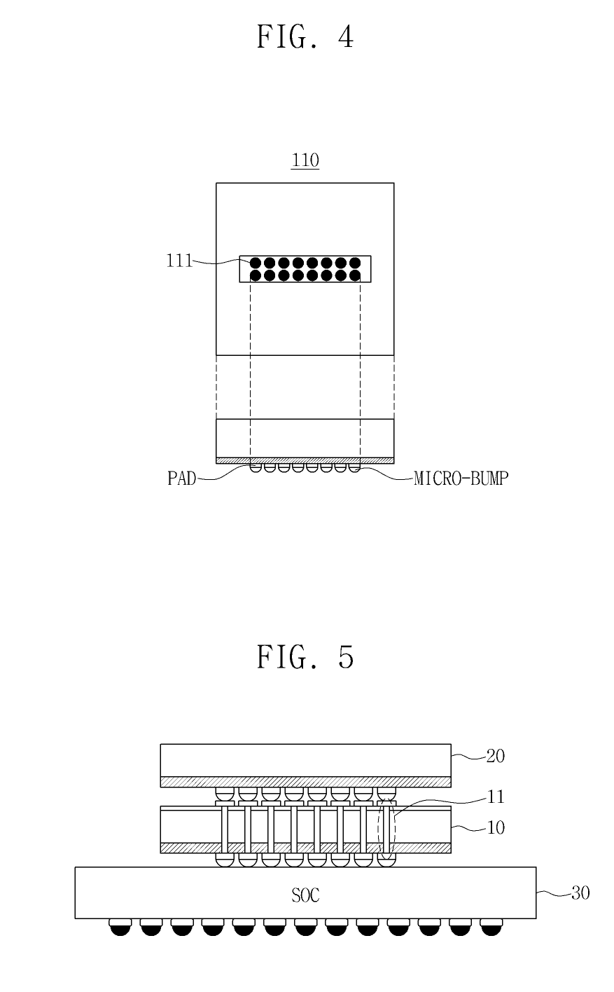

An exemplary structure of each of the first and second memory devices 110 and 120 will be explained in detail through FIG. 4.

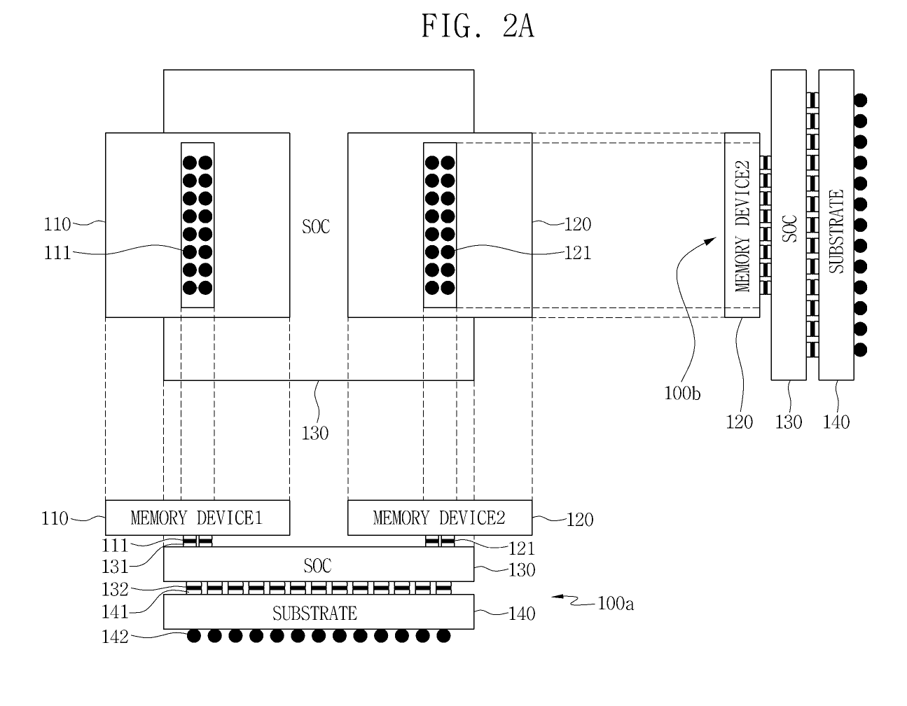

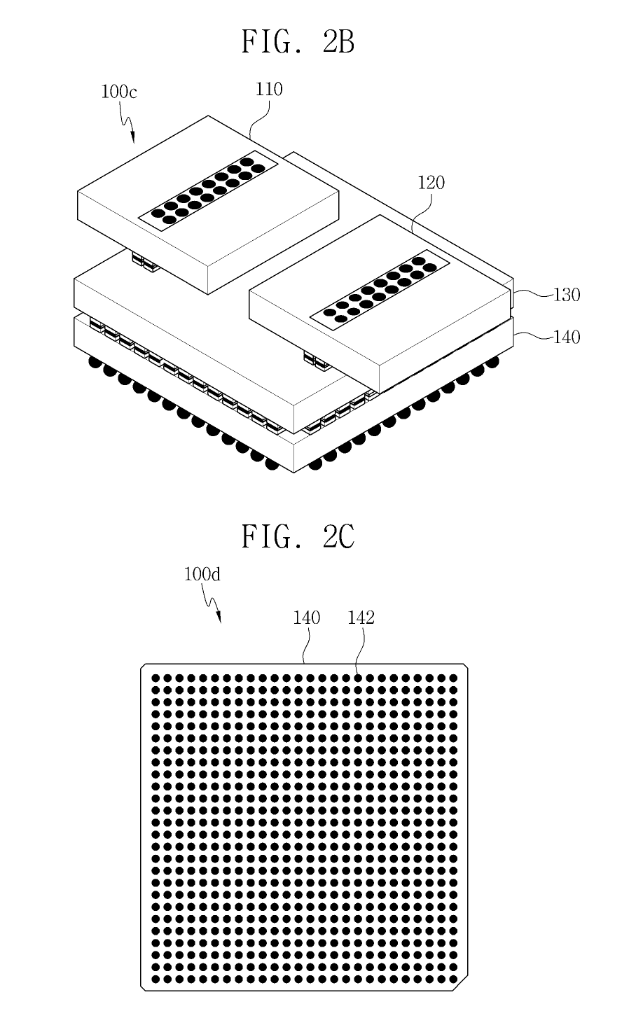

FIG. 2A shows the front and the side of the multi-chip package 100 shown in FIG. 1.

Referring to FIG. 2A, the front view 100a and the side view 100b of the multi-chip package 100 are shown.

As shown in FIG. 2A, plurality of pads 131 are mounted on the top of the SOC 130. Each of the plurality of pads 131 may be electrically connected to a first micro bump 111 or a second micro bump 121. Further, a plurality of pads are mounted on a bottom of the SOC 130, and each of the plurality of pads may be connected to one of a plurality of micro bumps 132. The combination of pads and terminals that connect between different parts of the multi-chip package 100 may be referred to herein generally as terminals.

In certain embodiments, the first and second micro bumps 111 and 121 and each of the plurality of pads on the SOC 130 may operate as a WideIO interface between the SOC 130 and the first and second memory devices 110 and 120. The WideIO interface may be described as including WideIO terminals. Examples of an SOC can be seen in U.S. Pat. No. 8,274,794, and examples of a WideIO interface can be seen in U.S. Pat. No. 5,796,662, both of which are incorporated herein in their entirety by reference.

A plurality of pads 141 for being connected electrically to the plurality of micro bumps 132 of the SOC 130 may be included on a substrate 140. Further, a plurality of solder balls 142 for being connected to a host (that is, an external system) may be included under the substrate 140. In one embodiment, the substrate 140 may be implemented by a printed circuit board (PCB).

FIG. 2B is an exemplary perspective view of the multi-chip package 100 shown in FIG. 1.

The perspective view 100c shown in FIG. 2b is an oblique view of the multi-chip package 100 shown in FIG. 1. When the plane, front, and side views of the multi-chip package 100 shown in FIG. 1 are shown simultaneously, the rear view cannot be seen. An exemplary rear view of the multi-chip package 100 shown in FIG. 1 is shown in FIG. 2C.

FIG. 2C is an exemplary rear view of the multi-chip package 100 shown in FIG. 1.

The rear view 100d shown in FIG. 2C shows the rear side of the multi-chip package 100 shown in FIG. 1. A bottom of the substrate 140 is constructed as a ball grid array (BGA). In one embodiment, each of the solder balls 142 mounted on the bottom of the substrate 140 may be connected to the external host (that is, the external system).

In other embodiments, however, the bottom of the substrate 140 may be constructed as a pin grid array PGA).

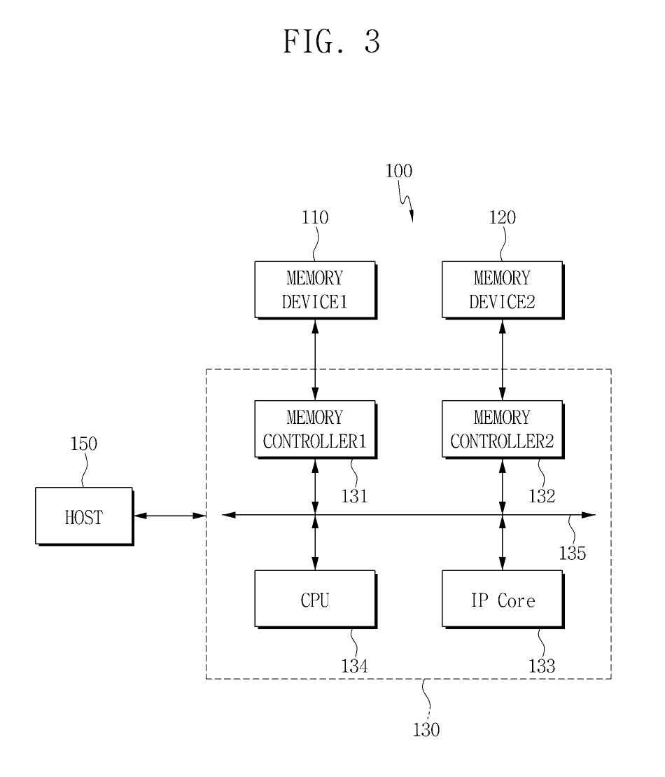

FIG. 3 is an exemplary system view inside the multi-chip package 100 shown in FIG. 1.

Referring to FIG. 3, the multi-chip package 100 includes the first and second memory devices 110 and 120, and the SOC 130 for accessing each of the first and second memory devices 110 and 120.

The SOC 130 includes first and second memory controllers 131 and 132 for controlling the first and second memory devices 110 and 120, respectively, an intellectual property (IP) core 133, a central processing unit (CPU) controlling the first and second memory controllers 131 and 132 and the IP core 133, and a system bus 135 connecting the first and second memory controllers 131 and 132, the IP core 133, and the CPU 134.

The IP core 133 accesses the first memory device 110 through the first memory controller 131 or accesses the second memory device 120 through the second memory controller 132. The first memory controller 131 and second memory controller 132 may be referred to collectively herein simply as a controller.

Depending on an embodiment, if the multi-chip package 100 is applied to a mobile product, the CPU 134 includes an ARM™ core, and the system bus 135 may be implemented by Advanced Microcontroller Bus Architecture (AMBA).

Referring to FIG. 1 to FIG. 3, the first memory device 110 and the first memory controller 131 are physically and electrically connected to each other through the first set of micro bumps 111, and the second memory device 120 and the second memory controller 132 are electrically connected to each other through the second set of micro bumps 121.

In one embodiment, the first and second memory devices 110 and 120, respectively have different physical traces to the IP core 133. For example, the first memory device 110 may be nearer to the IP core 133 than the second memory device 120. If so, for the IP core 133, preferentially accessing the first memory device 110 may be a method of reducing latency. As a result, latency in the SOC may depend on a physical trace from the IP core 133 to the memory device.

The latency described above means a time period from the time when the IP core 133 outputs a command to the first or second memory controller 131 or 132 to the time when the corresponding memory controller responds to the command of the IP core 133. The latency may also be referred to as a waiting time or a reaction time.

In certain embodiments, the IP core 133 may be implemented to include functions such as a video codec, audio, a Universal Serial Bus (USB) interface and so on. Examples of IP cores are described in U.S. Pat. No. 8,286,014, which is incorporated herein by reference in its entirety.

In one embodiment, each of the solder balls 142 mounted on the bottom of the substrate 140 may be connected to the host 150.

FIG. 4 is a front view of a first memory device 110 shown in FIG. 1, according to one exemplary embodiment.

Referring to FIG. 4, a plurality of pads and micro bumps 111 respectively connected to the plurality of pads are mounted on a bottom of the first memory device 110. The micro bumps 111 may be electrically connected to the pads 131 on the top of the SOC 130.

Although not shown in FIG. 4, in certain embodiments, the second memory device 120 may be implemented with the same structure of the first memory device 110.

Generally speaking, in order to satisfy a high memory bandwidth required for a DRAM, a WideIO may be used for the DRAM. The WideIO connects the DRAM with the SOC directly using TSV internal connection for the DRAM. A DRAM using the WideIO may be applied, for example, to a device performing an application program requiring a memory bandwidth over 12.8 GBps such as 3-dimensional (3D) gaming and a high-definition (HD) video.

The bandwidth means an amount of data transferred per unit time. As the unit of the bandwidth, bps (bits per second) may be used. As such, the bandwidth refers to the number of bits of data transferred in one second. Further, the memory bandwidth may refer to the number of bits of data transferred in one second from the first memory device 110 to the first memory controller 131.

The disclosed embodiments provide a multi-chip package using the WideIO without using TSVs. For example, a plurality of memory devices providing the WideIO may be stacked on more than one area of an SOC. They may be horizontally separated from each other rather than horizontally overlapping in a vertical stack. An exemplary memory device generally using the WideIO will be explained in detail using FIG. 5.

FIG. 5 shows a memory device using a WideIO.

Referring to FIG. 5, a memory device using the WideIO is generally stacked using the TSV. That is, the upper memory device 20 is stacked on a top of the lower memory device 10. The upper memory device 20 is electrically connected to the SOC 30 through the TSV 11 of the lower memory device 10.

Assuming that the lower memory device 10 has 512 WideIOs, the upper memory device 20 also has 512 WideIOs. As such, the upper memory device 20 uses the WideIO of the lower memory device 10 jointly. Accordingly, the SOC 30 accesses the lower memory device 10 and the upper memory device 20 through the 512 WideIOs.

However, according to the embodiments described herein, the first and second memory devices 110 and 120 shown, for example in FIG. 1, may be connected to the SOC 130 using two WideIOs. The two WideIOs may be horizontally separated and adjacent from each other. Therefore, the memory devices 110 and 120 according to certain embodiments may have a broader memory bandwidth.

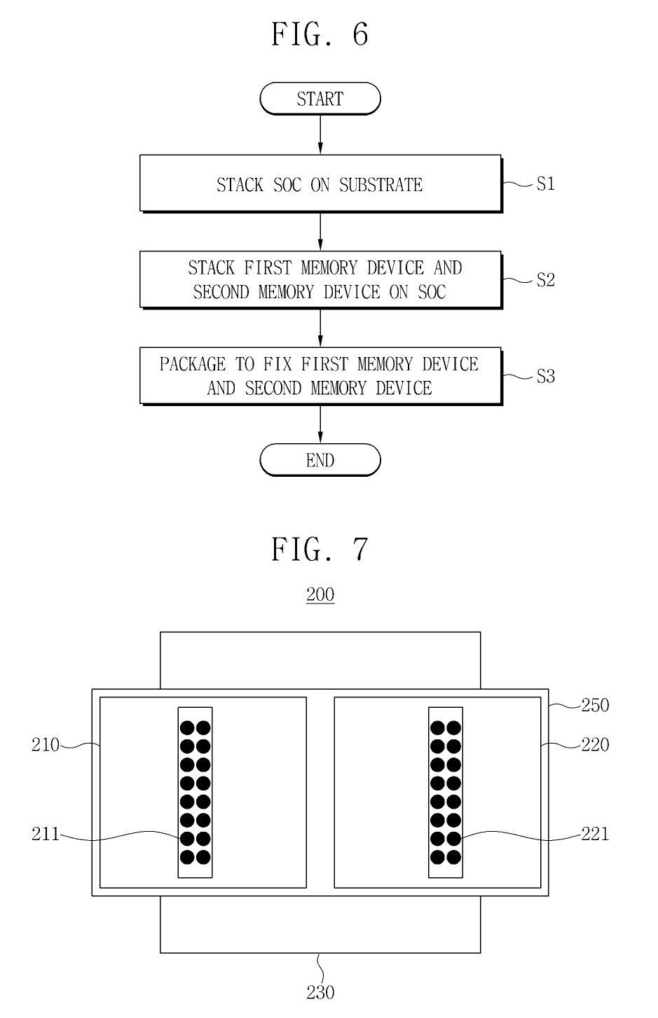

FIG. 6 is a flow chart illustrating an exemplary manufacturing method of the multi-chip package 100 shown in FIG. 1.

Referring to FIG. 1 to FIG. 6, in operation 51, the SOC 130 is stacked on the substrate 140. To be specific, the micro bumps 132 on the bottom of the SOC 130 are connected to the pads 141 on the top of the substrate 140. Accordingly, the substrate 140 and the SOC 130 are electrically connected.

In operation S2, the first and second memory devices 110 and 120 are stacked on the SOC 130. To be specific, the pads 131 on the top of the SOC 130 are connected to the micro bumps 111 on the bottom of the first memory device 110. Also, the pads 131 on the top of the SOC 130 are connected to the micro bumps 121 on a bottom of the second memory device 120. The first memory device 110 and the second memory device 120 are arranged in the same plane on the SOC 130 respectively.

In operation S3, packaging is performed so that the SOC 130 and the first and second memory devices 110 and 120 stacked on the SOC 130 are fixed.

FIG. 7 is a block view of a multi-chip package 200 in accordance with another exemplary embodiment.

Referring to FIG. 7, a multi-chip package 200 includes a chip 250 including first and second memory devices 210 and 220, and an SOC 230 controlling each of the first and second memory devices 210 and 220.

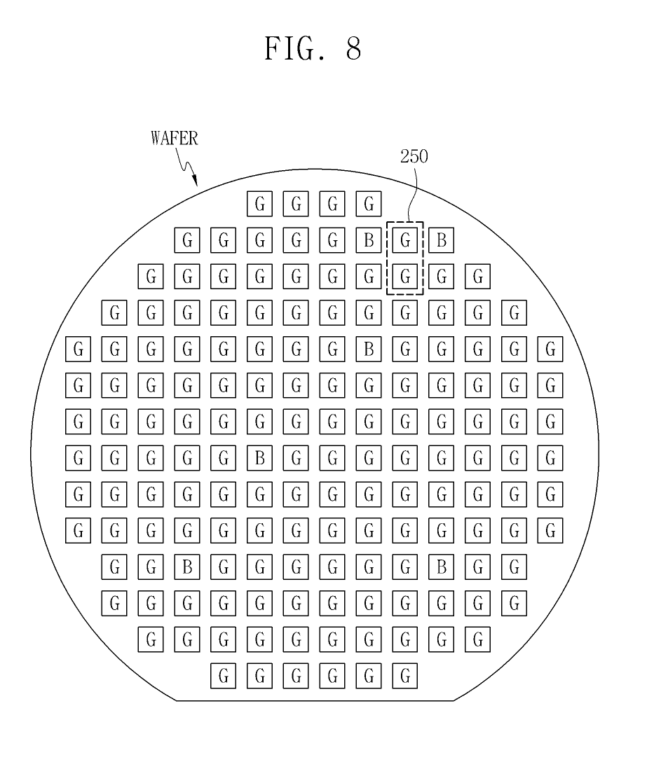

In one embodiment, the chip 250 is cut (e.g., sawed) so that except for a side between the first and second memory devices 210 and 220, the sides of the first and second memory devices 210 and 220 are sawn. As such, a scribe area between the first and second memory devices 210 and 220 of the chip 250 may be maintained while the rest of scribe areas are cut. In FIG. 7, the area labeled 250 is illustrated to appear larger than the area covered by the devices 210 and 220 and the scribe area between them. However, this is done in FIG. 7 merely to show the different named elements described above. As described above with regard to the cut portions, in one embodiment, the outer edges of the devices 210 and 220 may form the area referred to as chip 250. Accordingly, in one embodiment, the first and second memory devices 210 and 220 are manufactured from the same wafer and remain connected to each other when disposed on the SOC 230. The chip 250 according to an exemplary embodiment will be explained in detail using FIG. 8.

The scribe area is an area for cutting (e.g., sawing) a wafer surface horizontally or vertically using a diamond cutter, etc.

The chip 250 is stacked on a top of the SOC 230. That is, each of the first and the second memory devices 210 and 220 is stacked on the top of the SOC 230 in a non-overlapping state. Further the first memory device 210 may include a first set of micro bumps 211 to be electrically connected to the SOC 230, and the second memory device 220 includes a second set of micro bumps 221 to be electrically connected to the SOC 230. In one embodiment, each of the first and second sets of micro bumps 211 and 221 may serve as a WideIO interface.

FIG. 8 is an exemplary embodiment of a wafer including the chip shown in FIG. 7.

Referring to FIG. 7 and FIG. 8, the wafer includes a plurality of dies.

In one embodiment, automatic test equipment (ATE) tests each of the plurality of dies on the wafer. After testing, each of the plurality of dies is classified as either a good die G or a bad die B. The bad dies B are discarded, and only the good dies G are assembled into a package. Generally, each of the dies is cut to be assembled into a package.

However, in one embodiment, the chip 250 is cut to include two dies. Further, the chip 250 according to one embodiment may include good dies G only.

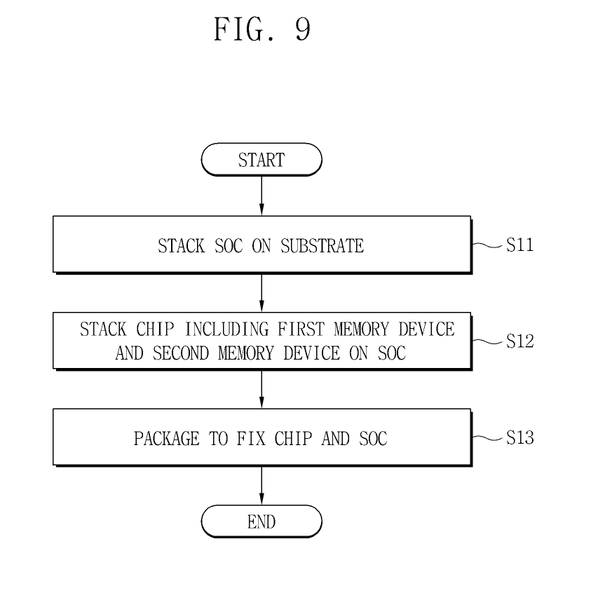

FIG. 9 is a flow chart illustrating a manufacturing method of the multi-chip package 200 shown in FIG. 7, according to one exemplary embodiment.

Referring to FIG. 7 to FIG. 9, in operation S11, the SOC 230 is stacked on the substrate 240. For example, the substrate 240 and the SOC 230 may be physically and electrically connected.

In operation S12, the chip 250 including the first and second memory devices 210 and 220 is stacked on the SOC 230. For example, the first memory device 210 and the second memory device 220 may be arranged in the same plane on the SOC 230 respectively.

In operation S13, packaging is performed so that the SOC 230 and the chip 250 stacked on the SOC 230 are fixed.

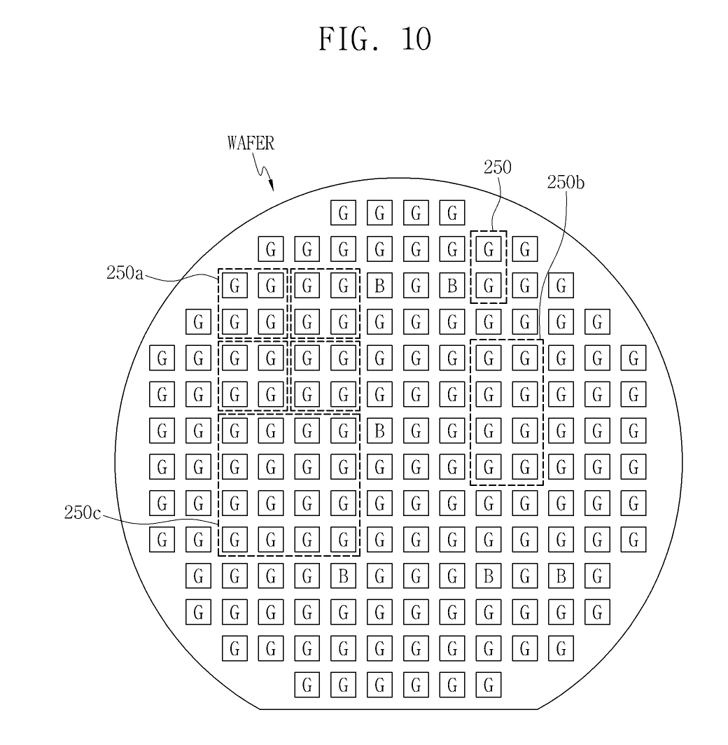

FIG. 10 is another exemplary embodiment of a wafer including the chip shown in FIG. 7.

Referring to FIG. 10, the wafer includes a plurality of dies. The plurality of dies include good dies G and bad dies B.

The chip 250 according to one embodiment is cut to include four dies, but is not limited to this.

For example, a chip 250a according to one embodiment may be cut to include four dies, and a chip 250b according to one embodiment may be cut to include eight dies. Further, a chip 250c according to one embodiment may be cut to include sixteen dies.

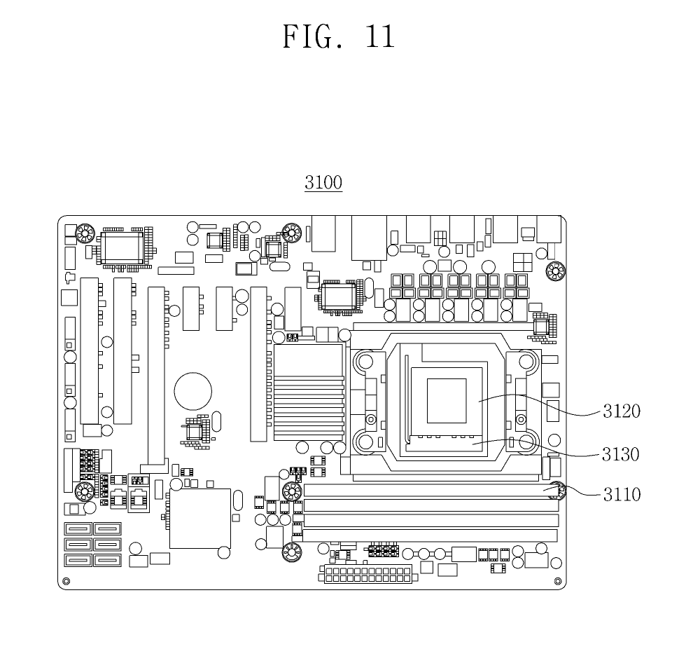

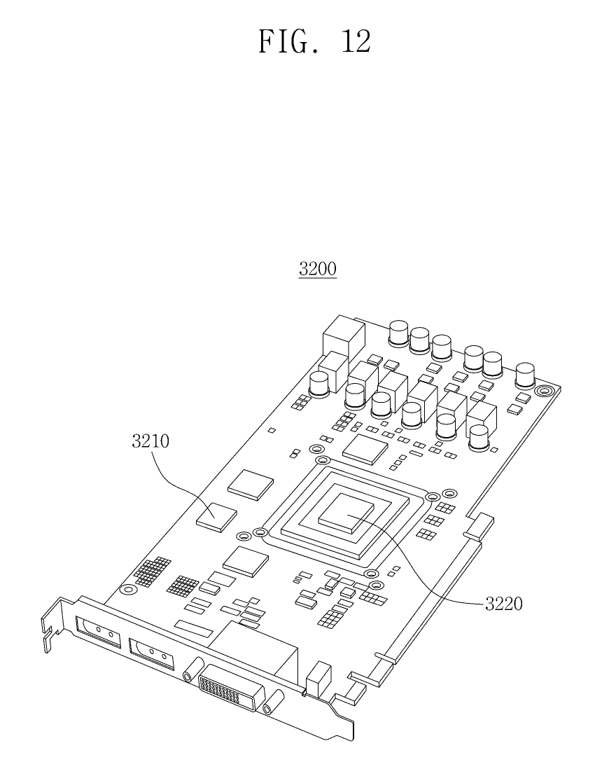

FIG. 11 shows an example of a main board including the multi-chip package 100 shown in FIG. 1.

Referring to FIG. 11, a main board 3100 includes a slot 3110 in which each of a plurality of memory devices is installed, a CPU 3120, and a socket 3130 on which the CPU 3120 is mounted.

The main board 3100, which may be referred to as a mother board, may include basic and physical hardware containing a basic circuit and components in a computer.

In one embodiment, the CPU 3120 may be implemented by a multi-chip package 100 or 200 such as shown in FIG. 1 or FIG. 7.

FIG. 12 shows an exemplary graphics card 3200 including the multi-chip package 100 shown in FIG. 1, according to one embodiment.

Referring to FIG. 12, the graphics card 3200 includes a plurality of video memory devices 3210 and a graphics processor 3220 processing image data stored in each of the plurality of video memory devices 3210.

In one embodiment, the graphic processor 3220 may be implemented by a multi-chip package 100 or 200 such as shown in FIG. 1 or FIG. 7.

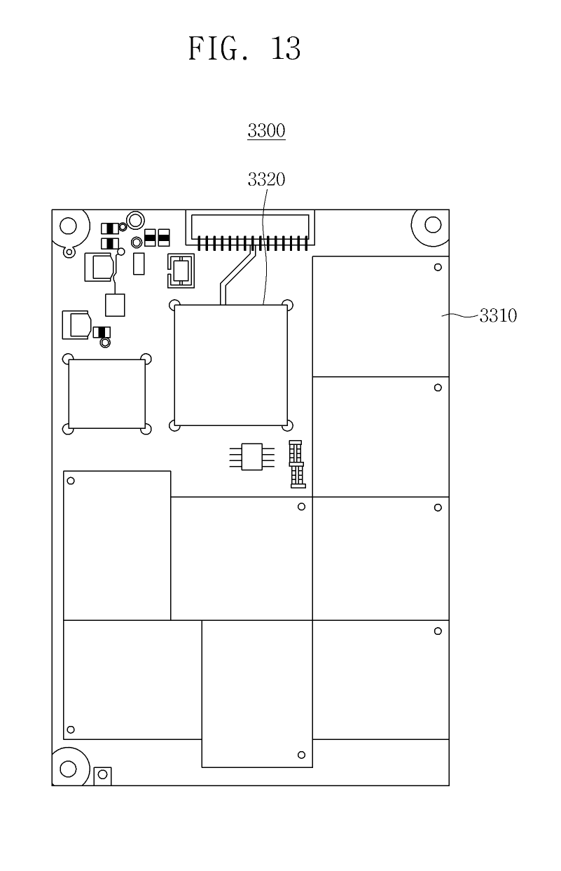

FIG. 13 shows an exemplary solid state drive (SSD) 3300 including the multi-chip package 100 or 200 shown in FIG. 1 or FIG. 7.

Referring to FIG. 13, the SSD 3300 includes a plurality of flash memory devices 3310, and an SSD memory controller 3320 controlling a data processing operation of each of the plurality of flash memory devices 3310.

In one embodiment, the SSD memory controller 3320 may be implemented by a multi-chip package 100 or 200 such as shown in FIG. 1 or FIG. 7.

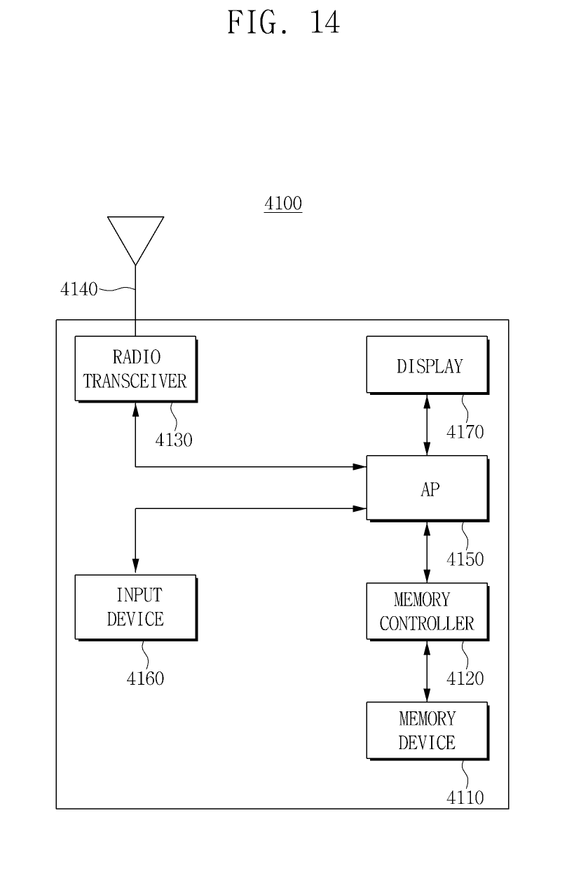

FIG. 14 shows one exemplary embodiment of a computer system 4100 including the multi-chip package 100 or 200 such as shown in FIG. 1 or FIG. 7.

Referring to FIG. 14, the computer system 4100 includes a memory device 4110, a memory controller 4120 controlling the memory device 4110, a radio transceiver 4130, an antenna 4140, an application processor 4150, an input device 4160 and a display 4170.

The radio transceiver 4130 may transmit or receive a radio signal through the antenna 4140. For example, the radio transceiver 4130 may change the radio signal received through the antenna 4140 into a signal which can be processed in the application processor 4150.

Therefore, the application processor 4150 may process the signal output from the radio transceiver 4130, and transmit the processed signal to the display 4170. Further, the radio transceiver 4130 may change the signal output from the application processor 4150 into a radio signal, and output the changed radio signal to an external device through the antenna 4140.

In one embodiment, the application processor 4150 may be implemented by a multi-chip package 100 or 200 such as shown in FIG. 1 or FIG. 7.

The input device 4160 is a device enabling input of a control signal for controlling operation of the application processor 4150 or data to be processed by the application processor 4150, and may be implemented by a pointing device such as a touch pad or a computer mouse, a keypad, or a keyboard.

The memory controller 4120 controlling operation of the memory device 4110 may be implemented as a part of the application processor 4150, or as a separate chip from the application processor 4150.

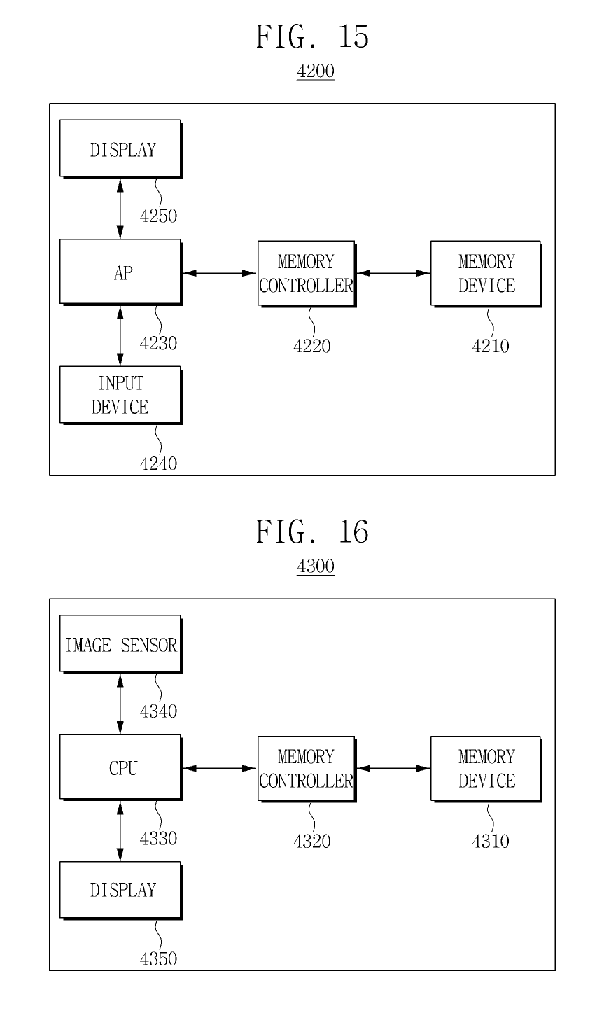

FIG. 15 shows another embodiment of a computer system 4200 including the multi-chip package 100 or 200 shown in FIG. 1 or FIG. 7.

Referring to FIG. 15, the computer system 4200 may be implemented by a personal computer (PC), a network server, a tablet PC, a net-book, an e-reader, a personal digital assistant (PDA), a portable multimedia player (PMP), an MP3 player or an MP4 player, for example.

The computer system 4200 includes a memory device 4210, a memory controller 4220 controlling a data processing operation of the memory device 4210, an application processor 4230, an input device 4240 and a display 4250.

The application processor 4220 may display, through the display 4250, data stored in the memory device 4210 according to data input through the input device 4240.

For example, the input device 4240 may be implemented by a pointing device such as a touch pad or a computer mouse, a keypad, or a keyboard. The application processor 4230 may control overall operation of the computer system 4200, and control operation of the memory controller 4220.

In one embodiment, the application processor 4230 may be implemented by a multi-chip package 100 or 200 such as shown in FIG. 1 or FIG. 7.

The memory controller 4220 controlling operation of the memory device 4210 may be implemented as a part of the application processor 4230, or as a separate chip from the application processor 4230.

FIG. 16 shows another embodiment of a computer system 4300 including the multi-chip package 100 or 200 shown in FIG. 1 or FIG. 7.

Referring to FIG. 16, the computer system 4300 may be implemented by an image process device, for example, a digital camera or a mobile phone, a smart phone, or a tablet with a digital camera attached.

The computer system 4300 includes a memory device 4310, and a memory controller 4320 controlling a data processing operation, for example, a write operation or a read operation of the memory device 4310. Further, the computer system 4300 includes a CPU 4330, an image sensor 4340 and a display 4350.

The image sensor 4340 converts an optical image into digital signals, and the converted digital signals are transmitted to the CPU 4330 or the memory controller 4320. According to the control of the CPU 4330, the converted digital signals may be displayed through the display 4350 or stored in the memory device 4310 through the memory controller 4320.

Further, the data stored in the memory device 4310 is displayed according to the control of the CPU 4330 or the memory controller 4320 through the display 4350.

In one embodiment, the CPU 4330 may be implemented by a multi-chip package 100 or 200 such as shown in FIG. 1 or FIG. 7.

The memory controller 4320 controlling operation of the memory device 4310 may be implemented as a part of the CPU 4330, or as a separate chip with the CPU 4330.

In the multi-chip package according to embodiments disclosed herein, a plurality of memory devices can be stacked on the same plane. Accordingly, as the plurality of memory devices are stacked without using the TSV in the multi-chip package according to certain embodiments, thus reducing the manufacturing cost.

The foregoing is illustrative of embodiments and is not to be construed as limiting thereof. Although a few embodiments have been described, those skilled in the art will readily appreciate that many modifications are possible in embodiments without materially departing from the novel teachings and advantages. Accordingly, all such modifications are intended to be included within the scope of this inventive concept as defined in the claims. In the claims, means-plus-function clauses are intended to cover the structures described herein as performing the recited function, and not only structural equivalents but also equivalent structures.

What is claimed is:

1. A multi-chip package, comprising:
a system on chip (SOC) including a central processing unit (CPU) and a memory controller;
a first memory device stacked on the SOC and electrically connected to the memory controller; and
a second memory device stacked on the SOC and electrically connected to the memory controller,
wherein the first memory device and second memory device are disposed in the same plane.

2. The multi-chip package of claim 1, wherein:
the first memory device comprises a first die; and
the second memory device comprises a second die separate from the first die.

3. The multi-chip package of claim 2, wherein:
the first die and second die are from the same wafer.

4. The multi-chip package of claim 2, wherein:
the first die and second die are from different wafers.

5. The multi-chip package of claim 1, wherein:
the first memory device and second memory device comprise a single die that forms a chip.

6. The multi-chip package of claim 1, further comprising:
a first set of micro-bumps physically and electrically connecting the first memory device to the SOC; and
a second set of micro-bumps physically and electrically connecting the second memory device to the SOC.

7. The multi-chip package of claim 6, wherein:
the first set of micro-bumps forms a first WideIO interface; and
the second set of micro-bumps forms a second WideIO interface.

8. The multi-chip package of claim 7, wherein:
each of the first WideIO interface and second WideIO interface includes at least 512 WideIO terminals.

9. The multi-chip package of claim 1, further comprising:
a substrate on which the SOC is mounted; and
a set of balls electrically and physically connecting the SOC to the substrate.

10. The multi-chip package of claim 9, wherein:
the substrate is a printed circuit board (PCB).

11. A multi-chip package, comprising:
a system on a chip (SOC);
a plurality of memory chips arranged in the same layer on the SOC;
a first set of terminals physically and electrically connecting a first memory chip of the plurality of memory chips to the SOC; and
a second set of terminals physically and electrically connecting a second memory chip of the plurality of memory chips to the SOC,
wherein the first set of terminals is horizontally adjacent to the second set of terminals.

12. The multi-chip package according to claim 11, wherein:
the first set of terminals comprise a first set of micro-bumps; and
the second set of terminals comprise a second set of micro-bumps.

13. The multi-chip package according to claim 11, wherein:
the first set of terminals forms a first wide input/output (WideIO) interface between the SOC and the first memory chip; and
the second set of terminals forms a second wide input/output (WideIO) interface between the SOC and the second memory chip.

14. The multi-chip package according to claim 13, wherein:
each of the first WideIO interface and second WideIO interface includes at least 512 WideIO terminals.

15. The multi-chip package according to claim 11, wherein:
the first memory chip and the second memory chip comprise an unseparated portion of a single wafer.

16. The multi-chip package according to claim 11, wherein the SOC includes:
a first memory controller for controlling the first memory chip;
a second memory controller for controlling the second memory chip; and
a central processing unit (CPU).

17. The multi-chip package according to claim 16, wherein the SOC further includes:
at least one intellectual property (IP) core for accessing the first memory chip through the first memory controller or for accessing the second memory chip through the second memory controller.

18. The multi-chip package according to claim 16, wherein:
the first memory chip is physically and electrically connected to the first memory controller through the first set of terminals, and
the second memory chip is physically and electrically connected to the second memory controller through the second set of terminals.

19. The multi-chip package according to claim 11, further comprising:
a substrate electrically connected to the SOC; and
a plurality of solder balls connected to the substrate and for communicating with an external host.

20. The multi-chip package according to claim 11, wherein each of the plurality of memory chips includes a DRAM.
